(19) United States
(12) Patent Application Publication
(10) Pub. No.: US 2012/0120574 A1
(43) Pub. Date: May 17, 2012

(54) SLIDING DEVICE AND A PORTABLE ELECTRONIC APPARATUS EMPLOYING THE SAME

(76) Inventor: HanSang Lee, Seoul (KR)

(21) Appl. No.: 13/384,711

(22) PCT Filed: Jun. 22, 2010
(86) PCT No.: PCT/KR10/04048

§ 371 Date: Jan. 18, 2012

(30) Foreign Application Priority Data
Jul. 20, 2009 (KR) 10-2009-0065786

(51) Int. Cl. H05K 7/00; F16H 21/44

(52) U.S. Cl. 361/679.01; 74/99 R; 74/100.1

(57) ABSTRACT

A device providing sliding and/or rotating motions for electronic devices or various structures is provided. The device includes a sliding step installed in a first body, a rail installed in a second body corresponding to the first body and for sliding the sliding step engaging the sliding step, a guide groove formed along a sliding direction on one of the first body and the second body, and a guide protrusion installed on the other of the first and second bodies, protruding toward the guide groove, engaging the guide groove, and moving along the guide groove in a mutual sliding motion between the first and second bodies.

### FIELD OF INVENTION

The invention relates to a sliding device for enabling a linear sliding motion, rotational sliding motion, or a linear sliding motion combined with a rotational sliding motion in an electronic device or various structures and a portable electronic device having such a sliding device.

### BACKGROUND OF INVENTION

The shape of portable terminals such as mobile phone, portable game machine, PDA, electronic scheduler, electronic dictionary, etc. keeps changing. Flip types, bar types, and folder types of mobile phone have been well known, and the slide type of mobile phones are developed already and on the market widely.

In general, a slide type portable terminal includes a cover and a body in which the cover is installed slidably. And the body and the sliding cover perform motions for folding on top of each other through mutual sliding motion or for releasing the folded status.

Several mechanisms for such a sliding motion have been suggested. There are a slide mechanism using a guide groove and a guide rail, a slide mechanism using a rack and a pinion, and a slide mechanism of a special structure using a slide member supported by a supporting plate, a guide plate formed with a guide hole for guiding the slide member, a plate spring, etc., all of which have problems of complicated and weak structure.

### DETAILED DESCRIPTION OF INVENTION

### Problems to Solve

The inventor recognizes that in the conventional slide type portable terminal the cover must slide along a straight line in both cases of opening and closing the cover, and found out a necessity of a sliding device, in which a cover can be opened and closed in a way other than a straight line.

Also, the inventor found other problems that, as recently functions of camera and video watching are included in a mobile phone, a cover of the mobile phone needs to be freely rotated in order to watch the video or image or for taking pictures horizontally or vertically on an LCD display provided on the cover of the mobile phone, but it is difficult to determine the location of a rotation axis so as to keep a left-right symmetry at a top portion of a first body while the cover is rotated.

An objective of the invention is to solve the above problems and to provide a sliding device including a guide groove and a guide rail for a sliding motion for an increased operation stability and simplified structure.

Another objective of the invention is to provide a rotational device including a guide groove and a guide rail for rotation motion for an increased operation stability and simplified structure.

Still another objective of the invention is to provide a device for sliding and rotating motions including a guide groove and a guide rail for sliding and rotating motions for an increased operation stability, simplified structure, and realizing sling and rotating motions at the same time.

Still another objective of the invention is to provide a sliding device which performs curved sliding motion and left-right-shaking sliding motion as well as a linear sliding motion in opening and closing.

Still another objective of the invention is to provide a sliding device which has a left-right symmetry automatically when rotating and opening-closing the cover.

Still another objective of the invention is to provide a portable electronic device including a sliding device according to the invention.

### Technical Solutions

An aspect of the present invention provides a sliding device combining a first body and a second body slidably with respect to each other, which comprises: a sliding step provided in the first body; a sliding rail provided in a second body corresponding to the sliding step, engaging, and sliding the sliding step; a guide groove formed in one of the first body and the second body along a direction of sliding; and a guide protrusion provided in the other of the first body and the second body, protruding toward the guide groove, engaging the guide groove, and moving along the guide groove during the sliding motion between the first body and the second body.

The sliding rail, the sliding step, and the guide groove may be provided in a straight line or in a curved line which is convex toward one direction in a middle portion.

One of the sliding step and the sliding rail, which is provided at the other of the first body and the second body, is installed slidably through a rotation member installation portion, and the guide groove may comprise one selected from the group consisting of a linear groove, a curved groove which is convex toward a side, and a groove having more than one zigzag bendings to right and left sides.

In some cases, a sliding device according to the invention is formed with a guide groove having a tilted groove portion tilted in a direction of width, and comprises: a first body comprising a slide plate with a sliding step at a side; a second body having a rotation member installation portion and a guide protrusion inserted to the guide groove, when the first body rotates, the guide protrusion applying a force to a side surface of the guide groove and allowing the first body perform a sliding motion; a rail plate engaged to a rotation member and comprising a rail engaging the sliding step so as to allow the first body to perform the sliding motion along with rotation.

The guide groove may further comprise a horizontal groove member connected to a side of the tilted groove portion.

The guide groove may comprise an upward tilted groove portion formed along a path which gets higher as going from one side to the other side and a downward tilted groove portion formed along a path which gets lower from the upward tilted groove portion.

The guide groove may further comprise a top-bottom extension groove portion formed along a path which is connected between the upward tilted groove portion and the downward tilted groove portion and extended top to bottom.

The second body comprises a top plate having a through hole for the rotation member installation portion, and the rotation member may be formed by comprising a circular plate member inserted into the through hole and engaged to the rail plate and a latch member having a diameter larger than the rotation member installation portion.

A cam groove is formed in the center of the rotation member, and may further comprise a tension roller device having an end fixed to the second body, inserted into the cam groove, and sticking to an inner wall of the rotation member.

The cam groove includes a curved guide path and stop grooves disposed with an interval in the curved guide path, and the tension roller device is formed with a pair facing each other and comprises: a torsion spring fixed to the second body; and a roller sticking to the guide path, providing a recovering force toward outside, and staying at the stop groove in the rotational motion so as to stay at a stop state.

The second body comprises a top plate having a through hole as the rotation member installation portion, and the rotation member comprises: a circular protrusion which is installed on a bottom surface of the rail plate and inserted into the through hole so as to support the rail plate to rotate in a right or left direction; and a ring body which is engaged to the circular protrusion at a bottom portion of the top plate so as to prevent the circular protrusion from falling off the through hole.

The guide groove may further comprise a vertical groove portion which is connected to the other side of the tilted groove portion and formed in a direction of length of the first body.

The vertical groove portion comprises one from a linear groove, a curved groove having a middle portion which is convex toward one side and a groove which has one or more bendings to the right and left sides in zigzag.

The device may further comprise a torsion spring, which has both ends rotatably connected to the first body and the second body respectively, rotates and performs compression and recovery following the sliding of the first body with respect to the second body, and pushes the first body by the rotation angle in a different direction.

A slide device according to the present invention comprises: a first body having a slide plate formed with a sliding step; a second body comprising a bottom plate, a top plate engaged to the bottom plate, and a circular rotation member installation portion provided in an upper portion of the top plate; a rotation member, in which a part of a top side is positioned to be inserted in the rotation member installation portion below the top plate and a bottom side is hooked in the rotation member installation portion and positioned in the second body; a rail plate which is engaged to the rotation member to rotate together and includes a rail engaging the sliding step so as to perform a sliding motion against each other,

wherein a guide groove is formed so as to form vertically in a direction of length in one of the first body and the second body and formed downward in a diagonal direction at an end,

wherein a guide protrusion is formed, which protrudes toward the guide groove in the other of the second body and the first body, engages the guide groove, and moves along the guide groove in sliding and/or rotating motions between the second body and the first body.

The guide groove is formed on a bottom surface of the slide plate, comprises a vertical groove portion formed vertically along a direction of length of the slide plate, a tilted groove portion formed downwardly along a direction of width extended from the vertical groove portion, and a horizontal groove portion connected to the tilted groove portion, and

the guide protrusion is formed so as to protrude from the second body, inserted into the guide groove and moves along, and may guide sliding and/or rotating motions of the first body in the second body.

A portable electronic device according to the present invention includes a sliding device according to the invention.

### Advantages

A sliding device according to the present invention may increase stability of operation by adopting a guide groove and a guide protrusion having path and shape appropriate for their movements. Additionally, simplifying the structure also provides an effect of improving efficiency of assembling.

A sliding device according to the present invention enables to obtain a left-right symmetry in rotational opening/closing of a cover automatically and allows a designer to adjust a location of rotation member installation portion since a location of left-right motions of the cover can be controlled easily according to the path of the guide groove and the installation location of the guide protrusion.

Also, by shaping the vertical groove portion of the guide groove in zigzag or a curve, various feeling of operation can be given to a user, and furthermore an effect of the user's experiencing unique interest in such various sliding motions can be expected.

A sliding device according to the present invention provides an effect of stable assembling structure and increased reliability of the device.

As in the above, since the present invention realizes linear sliding motion or rotating motion alone or collectively, it can be applied widely to many applications which need such motions. Especially, in a case of mobile phone, the sliding device makes it convenient to watch a display screen horizontally, and increases using both hands in a mobile game.

Embodiments described here present the most preferable examples just for help the community to understand out of various possible examples, but the art and technological spirit of the present invention are not limited to them, and it is still possible to apply various changes and modifications to have equivalent embodiments without leaving the scope of the present invention.

### BRIEF DESCRIPTION OF DRAWINGS

FIG. 1 is an exploded perspective view showing a sliding device realizing sliding and rotating motions concurrently according to a first embodiment of the present invention;

FIG. 2 is an enlarged exploded perspective view showing a core portion with second and first bodies removed in FIG. 1;

FIG. 3 is an exploded perspective view showing FIG. 1 as viewed from below;

FIG. 4 is an enlarged exploded perspective view showing a core portion of FIG. 3;

FIG. 5 is a partially assembled perspective view showing an assembled second body of FIG. 1;

FIGS. 6 through 8 are diagrams showing sliding motion of the first embodiment of the present invention;

FIGS. 9 and 10 are diagrams showing rotating motion of the first embodiment of the present invention;

FIG. 11 is an exploded perspective view showing a sliding device according to a second embodiment of the present invention;

FIG. 12 is an exploded perspective view showing FIG. 11 as viewed from below;

FIG. 13 is an exploded perspective view showing a rotating sliding device according to a third embodiment of the present invention;

FIG. 14 is an exploded perspective view showing FIG. 13 as viewed from below;

FIGS. 15 and 16 are a plan view and a perspective view showing a fourth embodiment of the present invention;

FIG. 17 is a plan view showing a fifth embodiment of the present invention;

FIGS. 18 and 19 are a plan view and a perspective view showing a sixth embodiment of the present invention, a variant of the second embodiment;

FIG. 20 is a plan view showing the seventh embodiment, a variant of the second embodiment;

FIG. 21 is a view of a guide groove according to another embodiment of the invention;

FIG. 22 is a perspective view showing a sliding device according to still another embodiment of the invention;

FIG. 23 is an exploded perspective view showing the sliding device of FIG. 22;

FIG. 24 is an exploded perspective view showing FIG. 23 as viewed from below;

FIG. 25 is a perspective view showing a status of a first body rotated and opened clockwise;

FIG. 26 is a perspective view showing a status of a first body rotated and opened counterclockwise; and

FIG. 27 is a perspective view showing a status of a first body opened upward.

### BEST MODES OF INVENTION

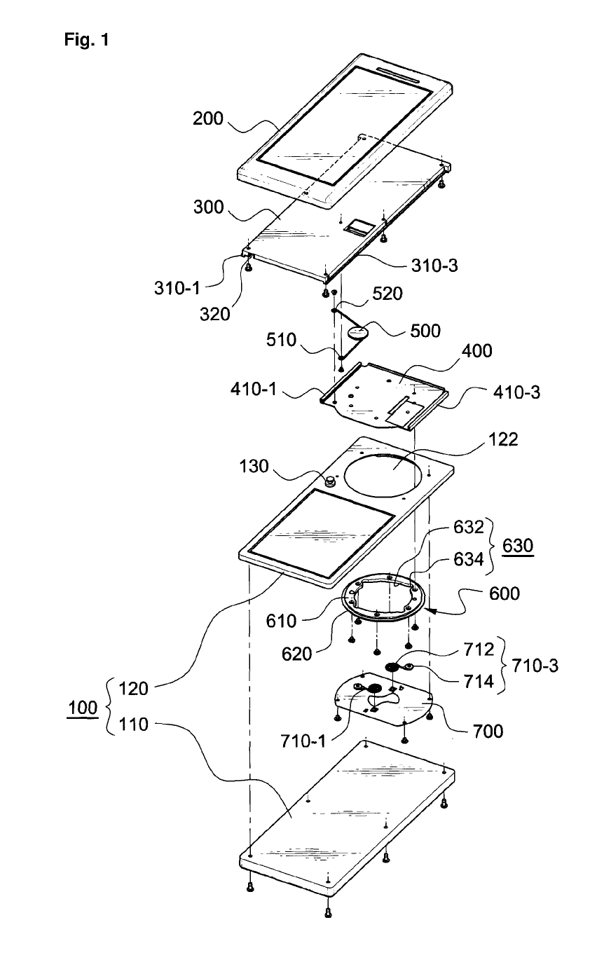

The invention is described in detail referring to the figures below. A sliding device of the present invention may be applied to various types of electronic devices, and the embodiments explain the devices applied to mobile phones. First, referring to FIGS. 1 through 10, a first embodiment of the present invention is explained.

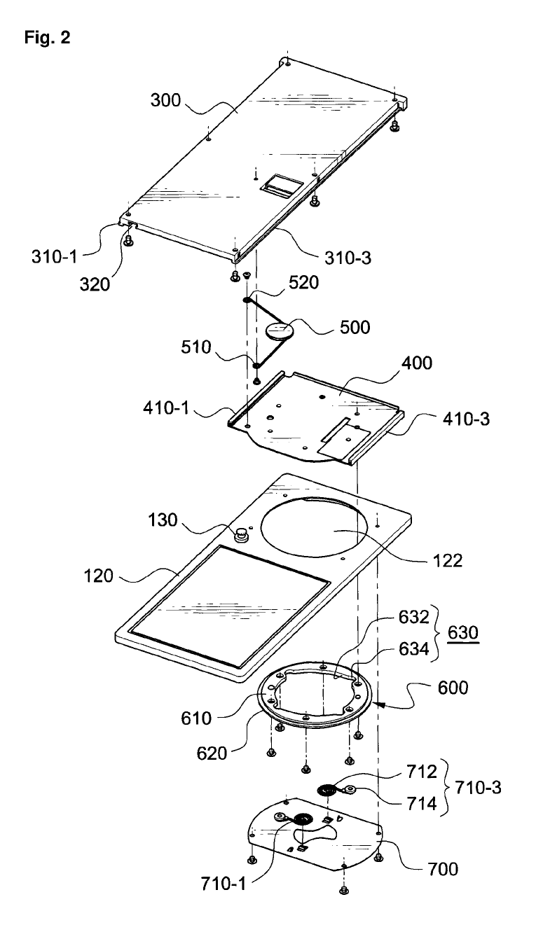

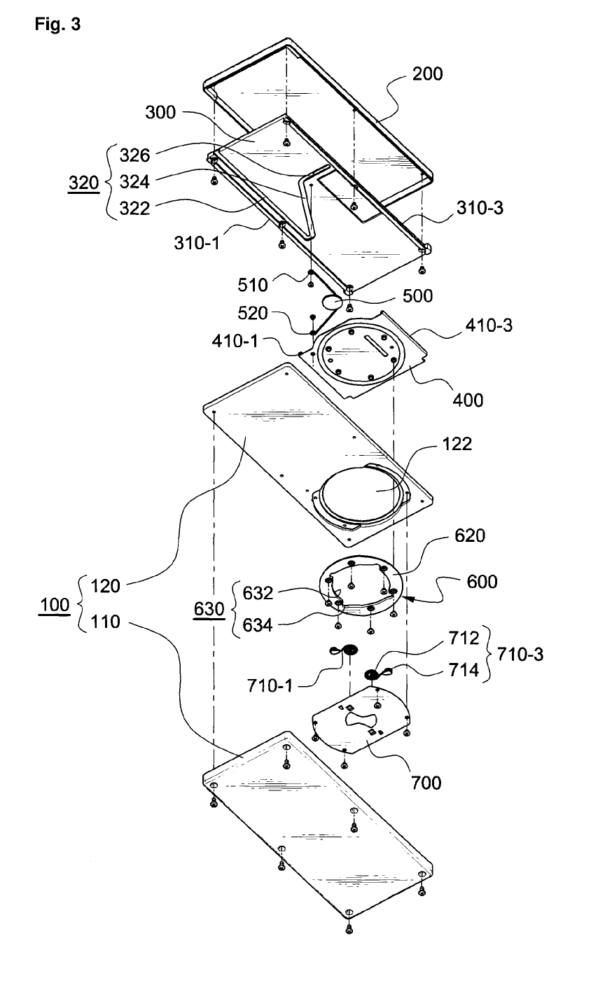

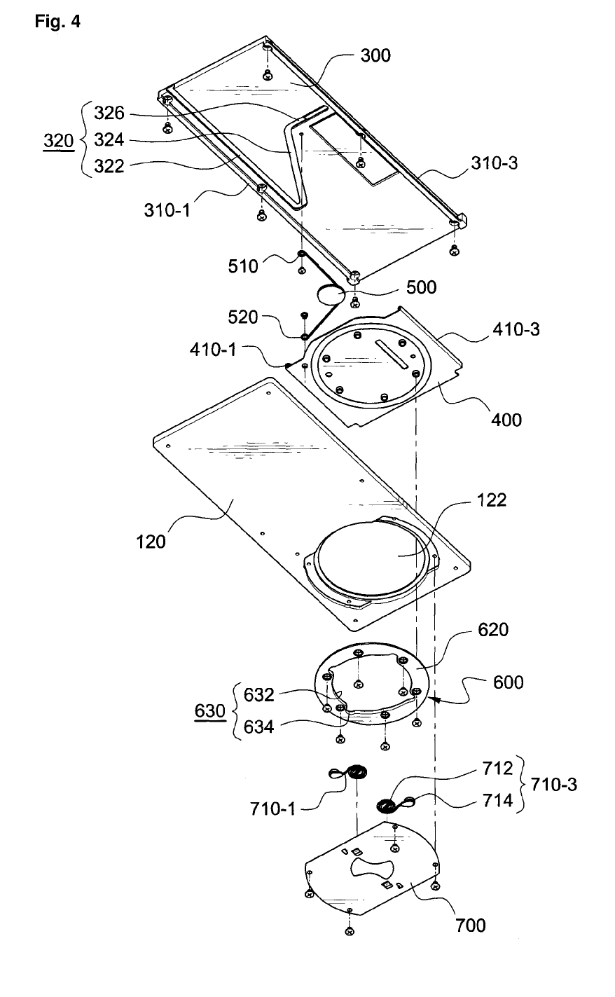

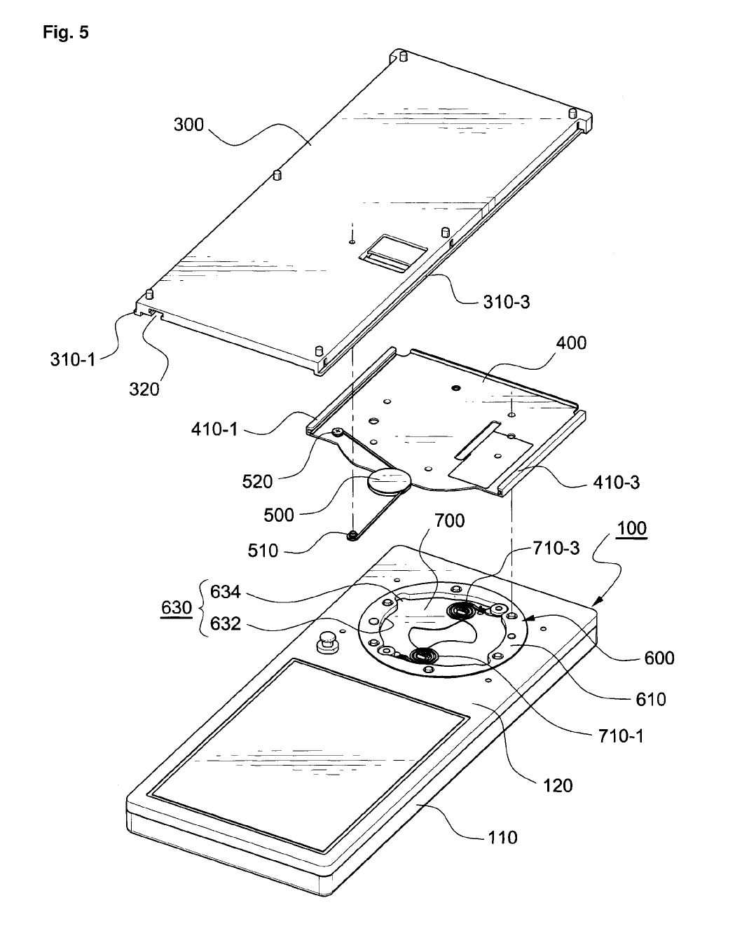

FIG. 1 is an exploded perspective view showing a sliding device realizing sliding and rotating motions concurrently according to a first embodiment of the present invention, and FIG. 2 is an enlarged exploded perspective view showing a core portion with second and first bodies removed in FIG. 1. FIG. 3 is an exploded perspective view showing FIG. 1 as viewed from below, and FIG. 4 is an enlarged exploded perspective view showing a core portion of FIG. 3. FIG. 5 is a partially assembled perspective view showing an assembled second body of FIG. 1.

The present invention comprises a sliding mechanism in which two members, that is a first body and a second body, engage each other enabling a linear sliding with respect to each other, and a rotating mechanism in which the first body and the second body engage each other enabling rotating with respect to each other. In the illustrated first embodiment, a slide-type mobile phone is shown, where the cover is the first body and the main body of the mobile phone is the second body. In certain cases, the first body may be the main body of the mobile phone, and the second body may be the cover of the mobile phone.

In this embodiment, a sliding mechanism applied to the slide mobile phone is a rail-type sliding mechanism for sliding the first body (200) on the second body (100) and formed inbetween. More specifically, the mobile phone is formed as the second body (100) and the first body (200) which is installed at a top side of the second body (100) and slides on the second body (100). In order for the first body (200) to slide on the second body (100), a sliding mechanism is formed in a facing portion between the first body (200) and the second body (100). That is, in this embodiment, sliding steps (310-1, 310-3) are provided on a rear surface of the first body (200), and rails (410-1, 410-3) are provided and engage the sliding steps (310-1, 310-3) at a top portion of a front surface of the second body (100) facing the rear surface of the first body (200) so as to guide the sliding steps to slide. Such sliding steps (310-1, 310-3) of the first body (200) are formed in a direction of length on both sides of a plate (300; referred as “slide plate” below) fixed to the rear surface of first body (200) as illustrated, and the rails (410-1, 410-3) are formed as a separate plate (400; referred as “rail plate” below) and fixed to the upper part of the front surface of the second body (100).

The device comprises a torsion spring (500) for facilitating smoother sliding motion by increasing operational force of user in sliding motion. This torsion spring (500) is disposed between the rail plate (400) and the slide plate (300), and the one end (510) is connected rotatably to the slide plate (300) and the other end (520) is connected rotatably to the rail plate (400), so as to provide an elastic force from compression and recovery when the first body (200) slides on the second body (100). Thereby the user can perform the sliding operation easily by exerting a small force.

On the other hand, the rotating mechanism of the present invention comprises a rotation member (600) engaging rotatably the second body (100). The rotation member (600) is preferably a circular plate, and a circular plate member (610) at the top has a diameter slightly smaller than that of a latch member (620) at the bottom, forming a step. The rotation member (600) is disposed between a bottom plate (110) and a top plate (120) of the second body (100) and engages rotatably, for which a rotation member installation portion (122) is formed at a top side of the top plate (120) of the second body. The rotation member installation portion (122) in this embodiment has a shape of a through hole, and has a diameter slightly larger than that of the circular plate member (610) and smaller than that of the latch member (620) so as to dispose the circular plate member (610) of the rotation member (600) therein. By engaging the top plate (120) with the bottom plate (110) of the second body while inserting the rotation member (600) at the bottom side of the top plate (120) of the second body by a structure such a rotation member installation portion (122), the rotation member (600) does not fall off from the second body (100) and the circular plate member (610) of the rotation member (600) can be disposed in the rotation member installation portion (122) rotatably. Here, a top surface of the circular plate member (610) of the rotation member (600) disposed in the rotation member installation portion (122) is preferably aligned with a top surface of the top plate (120) of the second body at about the same height. More preferably, a support plate (700) may be engaged to the bottom surface of the top plate (120) of the second body (100) so as to support a bottom side of the rotation member (600). The rotation member (600) is engaged to the rail plate (400) described in the above, and then engages the rail plate (400) to a top side of the second body (100). Therefore the rotation member (600) and the rail plate (400) rotate integrally in the second body (100). Especially, the circular rotation member (600), supported by the circular rotation member installation portion (122), rotates with it.

Also, the device additionally provides a structure for guiding rotating motion more stably and smoothly and stopping at a predetermined angle. To explain this rotation guiding means further, a cam groove (630) is formed in a central portion of the rotation member (600), and tension roller devices (710-1, 710-3) installed in the support plate (700) stick along the cam groove (630). These tension roller devices (710-1, 710-3) comprise a roller (714) installed in an open end of the torsion spring (712) having an end fixed to the support plate (700) and exerting a recovering force toward outside, and the roller (714) moves along the cam groove (630). Desirably, the cam groove (630) comprises stop grooves (634) which has a diameter farther than the guide path (632) from the center of the rotation member (600) every 90 degrees in the curved guide path (632). Thereby when the rotation member (600) rotates the tension roller devices (710-1, 710-3) move along the guide path (632) and stop smoothly at 90 degrees. This makes, when the first body (200) rotates in the second body (100), the first body (200) rotate without shaking and stop at 90 degrees from the first body (200) at the same time. The tension roller devices (710-1, 710-3) are preferably provided as a pair which face each other about the center of the rotation member (600) as a center point.

The present invention comprises a guide groove (320) and a guide protrusion (130) for guiding stably linear sliding and rotating motions. The guide groove (320) is formed at a bottom surface of the slide plate (300), a bottom plate of the first body (200) as shown in FIG. 3, and comprises a vertical groove portion (322) formed along a direction of length of the slide plate (300), a tilted groove portion (324) connected from a top inner end portion of the vertical groove portion (322) obliquely to a bottom end, and a horizontal groove portion (326) extended horizontally from an end of the tilted groove portion (324). Especially, the vertical groove portion (322) is preferably formed around an end of the first body (200). On the other hand, the guide protrusion (130) protrudes from a top side edge of the top plate (120) of the second body, which faces the vertical groove portion (322). At an end of the guide protrusion (130) is formed a latch step, so as to engage the guide groove (320) in order not to fall off in an insertion.

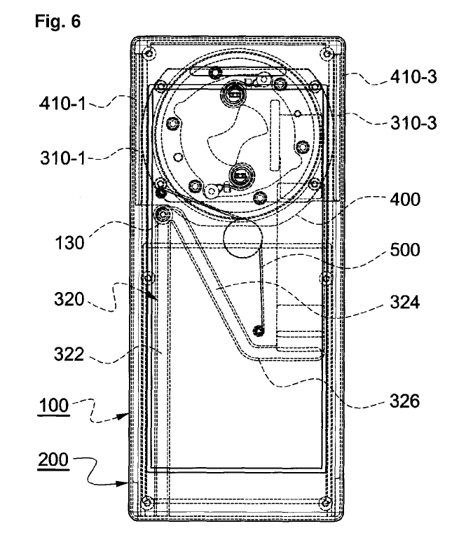

The vertical groove portion (322) in the guide groove (320) is for a linear sliding motion along a top-bottom direction, and the tilted groove portion (324) and the horizontal groove portion (326) are for a rotating motion. Referring to FIGS. 6-8, if the guide protrusion (130) moves along the vertical groove portion (322), the first body (200) slides in a straight line in the second body (100). Referring to FIGS. 6, 9, and 10, if the guide protrusion (130) moves along the tilted groove portion (324) and the horizontal groove portion (326), it rotates.

The guide groove (320) and the guide protrusion (130) explained so far in provided in the slide plate (300) formed in the first body (200) and the second body (100) respectively, but on the contrary the guide groove may be formed in the second body, and the guide protrusion in the plate. Furthermore, the slide plate may be integrated with the first body, or may be formed separately and installed. That is, since the sliding motion is a mutual motion between the first body and the second body, the guide groove and the guide protrusion can change their positions.

As a result, the vertical sliding mechanism is realized by a structure of the sliding steps (310-1, 310-3) and rails (410-1, 410-3) and engagement of the vertical groove portion (322) of the guide groove (320) and the guide protrusion (130), and the rotating mechanism is realized by a structure of the rotation member (600) engaged to the rail plate (400) and the rotation member installation portion (122) and engagement of the tilted groove portion (324) of the guide groove (320), the horizontal groove portion (326), and the guide protrusion (130). Therefore, it is possible to separate the vertical sliding mechanism and the rotating mechanism and to make a sliding device for sliding only and a rotating device for rotating only. The vertical sliding device is described in a second embodiment of the present invention, and the rotating sliding is in the third embodiment of the present invention.

FIGS. 6 through 8 are operation diagrams showing sliding motion of the first embodiment of the present invention.

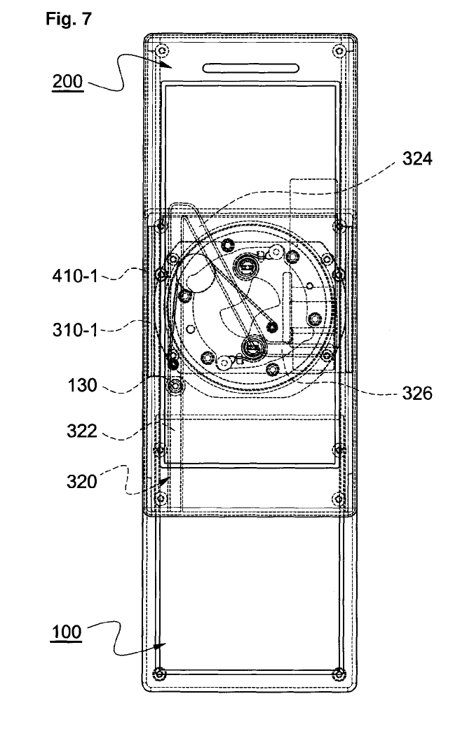

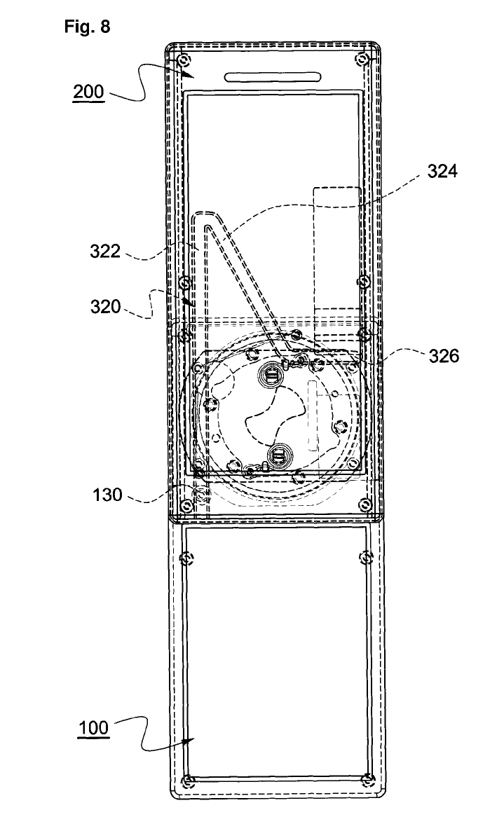

The vertical sliding motion is performed by a user's pushing the first body (200) from the second body (100) upward. If pushing the first body (200) upward, the sliding steps (310-1, 310-3) provided on both sides of a bottom surface of the first body (200) move along the pair of rails (410-1, 410-3) at both sides of the rail plate (400) engaging a top portion of the second body (100). At the same time, the guide protrusion (130) moves its position from a top side to a bottom side along the vertical groove portion (322) of the guide groove (320). More specifically, when the first body (200) is on top of the second body (100) (before the operation), the guide protrusion (130) is positioned in a topmost position of the vertical groove portion (322) as shown in FIG. 6. If pushing the first body (200) with a hand in such state, the first body (200) rises and the guide protrusion (130) formed in the second body (100) goes down along the vertical groove portion (322). That is, FIG. 7 shows a middle point in the operation, where the guide protrusion (130) passes a middle point of the vertical groove portion (322) and keeps descending, until as in FIG. 8 after the sliding motion the guide protrusion (130) is positioned approximately at a lowest position of the vertical groove portion (322) such that the first body (200) is fully opened and is at a highest operational position. At this moment, the torsion spring (500) goes to a middle operational point and is compressed as shown in FIG. 7 as the first body (200) rises, and if passing the middle position, when going back to the highest operational position, the elastic recovering force is applied to the first body (200) and, if the user pushes just to the middle point, helps the first body (200) to go all the way to a position of operation end.

As shown, the sliding motion can be obtained with a small handling force of the user by installing the torsion spring (500), and also the reliability of operation can be obtained.

It is also possible to perform the operation described in the above in reverse order in closing the opened first body (200).

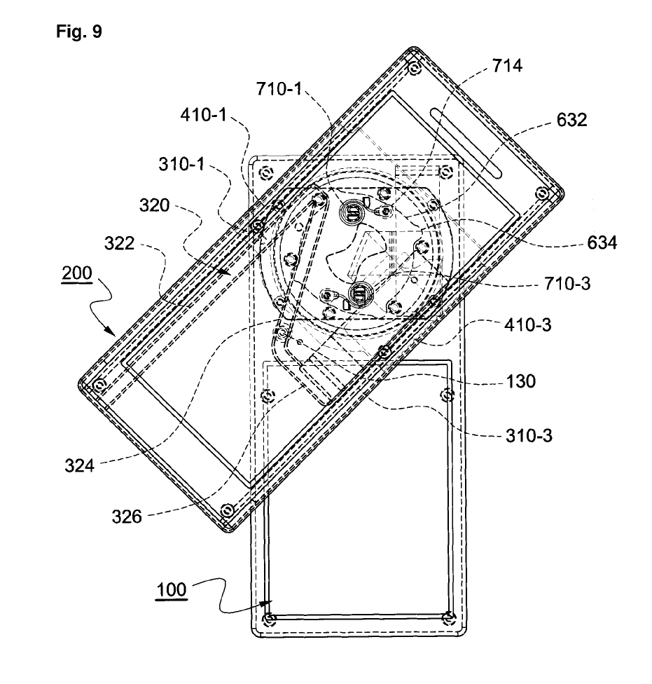

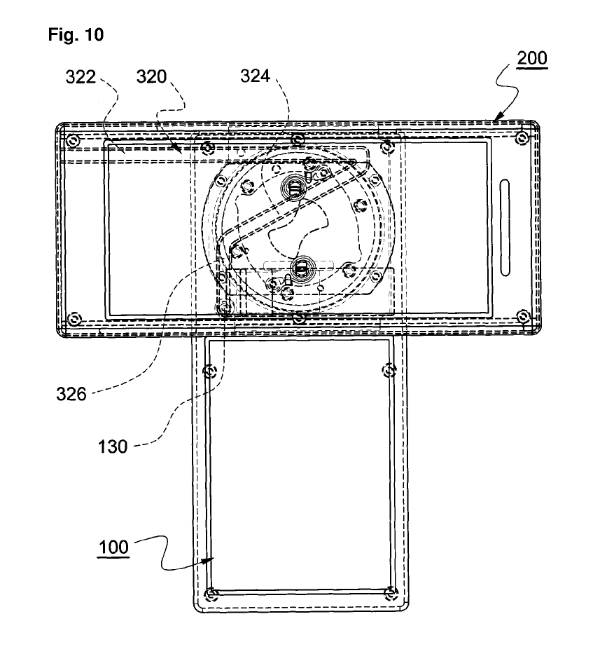

FIGS. 9 and 10 are diagrams showing rotating motion of the first embodiment of the present invention.

If the user rotates the first body (200) when the first body (200) is on top of the second body (100) as shown in FIG. 6, the rail plate (400) engaged to the sliding steps (310-1, 310-3) of the first body (200) rotate in the rotation member installation portion (122) integrally with the rotation member (600) engaged to the rotation member installation portion (122) of the second body (100). At this moment, the guide protrusion (130) moves along the tilted groove portion (324) of the guide groove (320) as shown in FIG. 9, and then the sliding steps (310-1, 310-3) slide for a specific distance on the rails (410-1, 410-3), such that the first body (200) rotates and rises at the same time. If kept rotating, as shown in FIG. 10, the guide protrusion (130) passes the tilted groove portion (324), moves along the horizontal groove portion (326), and stops at an end of the horizontal groove portion (326). Then, as the first body (200) rotates and slides for a specific distance by the structure of the tilted groove portion (324) and the horizontal groove portion (326), if the first body (200) rotates by 90 degrees and stops, a middle portion of the first body (200) is positioned at a top portion of the second body (100), finishing in a shape of letter T. Here, the horizontal groove portion (326) interacts with the guide protrusion (130) and performs an operation for determining left-right positions, such that the first body (200) is at a left-right symmetrical position.

Especially, with rotating motion, rollers (714) of the pair of tension roller devices (710-1, 710-3) push the guide path (632) toward outside, move along, and finally come to next stop grooves (634) and stop. Since a stop groove (634) and the next stop groove are formed with an interval of 90 degrees, the rotating motion of the first body (200) stops and is fixed smoothly after rotation of 90 degrees. In rotating, the first body (200) rotated by the elastic force of the tension roller devices (710-1, 710-3) can operates stably without shaking, stop at a precise location (90 degrees), and keep the stopped state.

### Embodiments of Invention

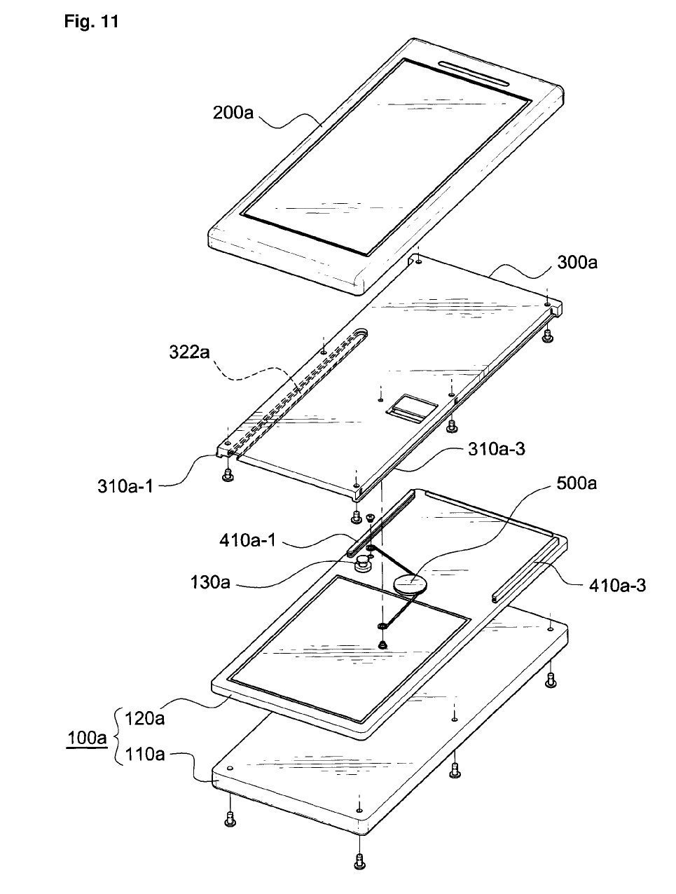

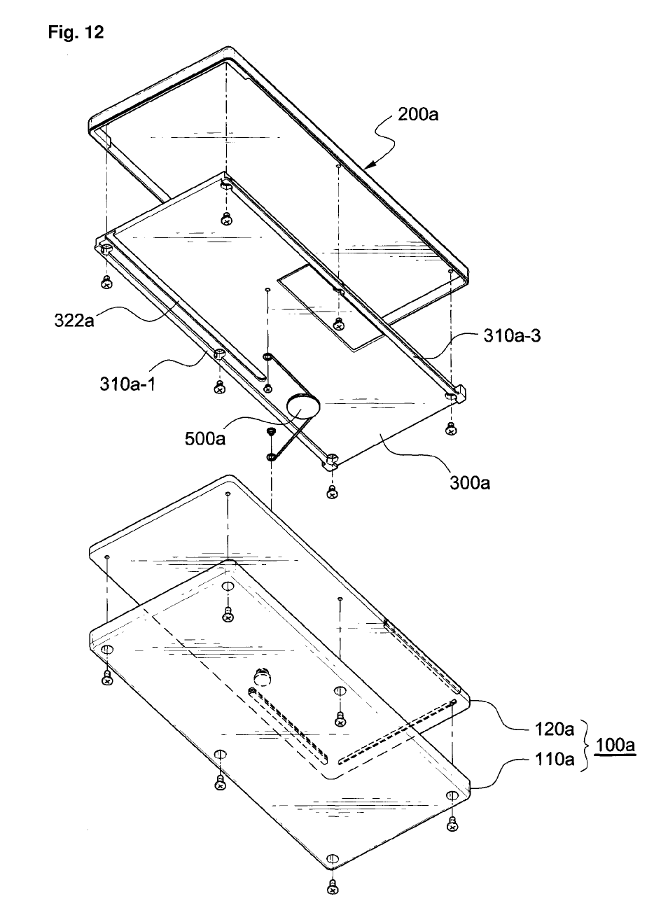

FIG. 11 is an exploded perspective view showing a sliding device according to a second embodiment of the present invention, and FIG. 12 is an exploded perspective view showing FIG. 11 as viewed from below.

As illustrated, a guide groove comprises a vertical groove portion (322a) formed along a direction of length of the slide plate (300a) installed at a bottom surface of a first body (200a), and a guide protrusion (130a) protruded from the top plate (120a) of the second body into the vertical groove portion (322a), and moves along in a straight line so as to guide sliding motion of the first body (200a) and the second body (100a). Here, a pair of sliding steps (310a-1, 310a-3) are formed on both sides of the slide plate (300a), and a pair of rails (410a-1, 410a-3) are integrally formed protruding on right and left sides on a top side surface of the corresponding top plate (120a). On the other hand, since a torsion spring (500a) installed between the top plate (120a) and the slide plate (300a) for increasing the sliding force by increasing the user's operating force is same in structures and operations as in the first embodiment, the description is omitted here.

The operation of the sliding device of the structure described above are same as that of the sliding device according to the first embodiment.

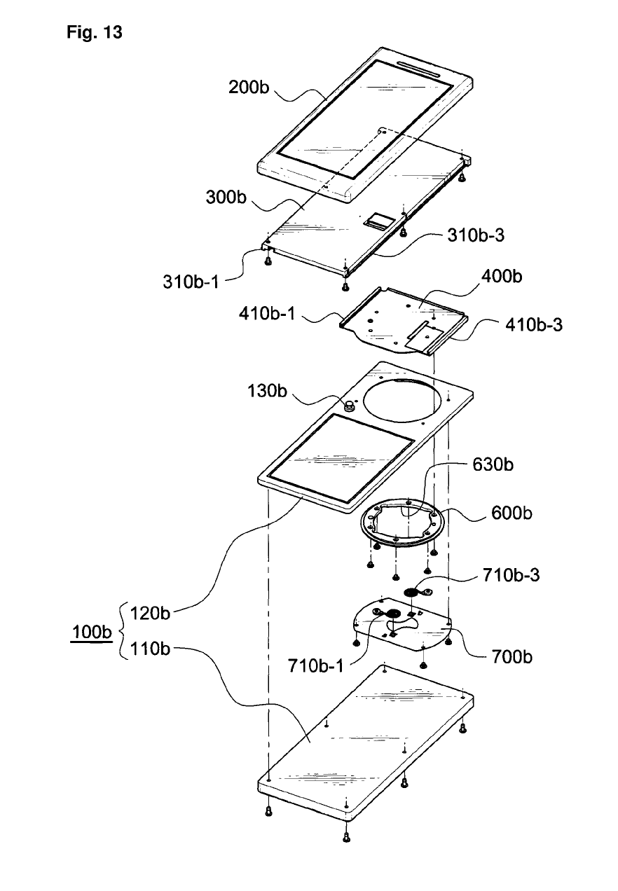

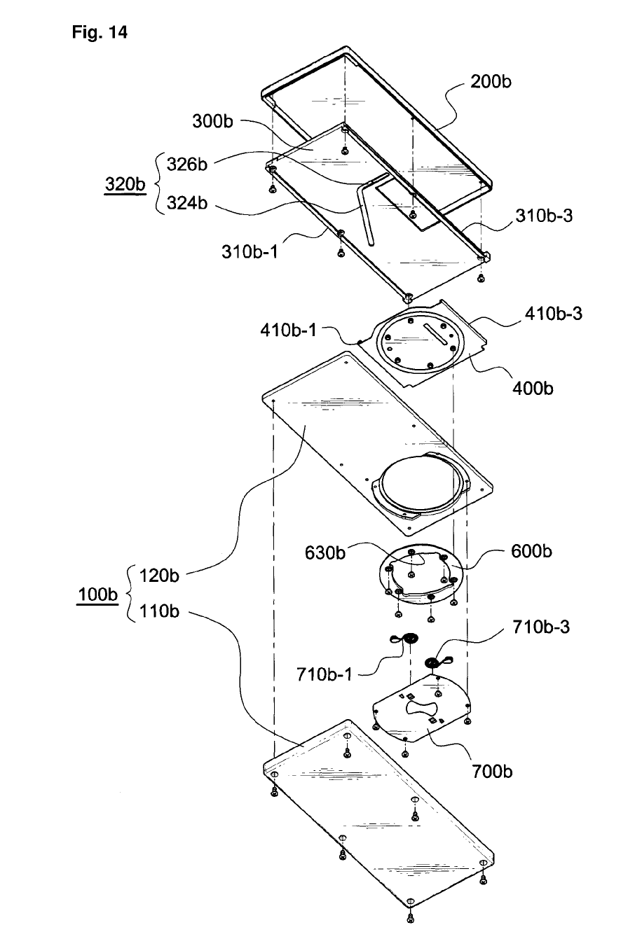

FIG. 13 is an exploded perspective view showing a rotating sliding device according to a third embodiment of the present invention, and FIG. 14 is an exploded perspective view showing FIG. 13 as viewed from below.

The rotating sliding device provides a guide groove (320b) installed at a bottom surface of a slide plate (300b), with a vertical groove portion for guiding sliding motion removed from the first embodiment, and comprising a tilted groove portion (324b) and a horizontal groove portion (326b) extending from an end of the tilted groove portion (324b). Thereby, when a first body (200b) rotates with respect to a second body (100b), a guide protrusion (130b) moves along a tilted groove portion (324b) and a horizontal groove portion (326b) and guides the rotating motion.

In certain embodiments, slope of the tilted groove portion (324b) may be small, and the guide groove (320b) may be formed without a horizontal groove portion (326b).

Other rotation mechanism is same as that of the first embodiment described already. That is, a rotating motion is performed concurrently with the linear sliding, a middle portion of the first body (200b) is positioned on a central line of the second body (100b), and all same as the first embodiment are the structure of sliding steps (310b-1, 310b-3) and rails (410b-1, 410b-3) so as to form a T shape after rotation, the structure of engaging of the rotation member (600b) and the rail plate (400b), and the structure of tension roller devices (710b-1, 710b-3) installed in the cam groove (630b) and the support plate (700b-1) and for pushing an inner wall surface of the cam groove (630b).

Also, since the operational mechanism of the rotating device is same as that of the first embodiment described already, more description is omitted here.

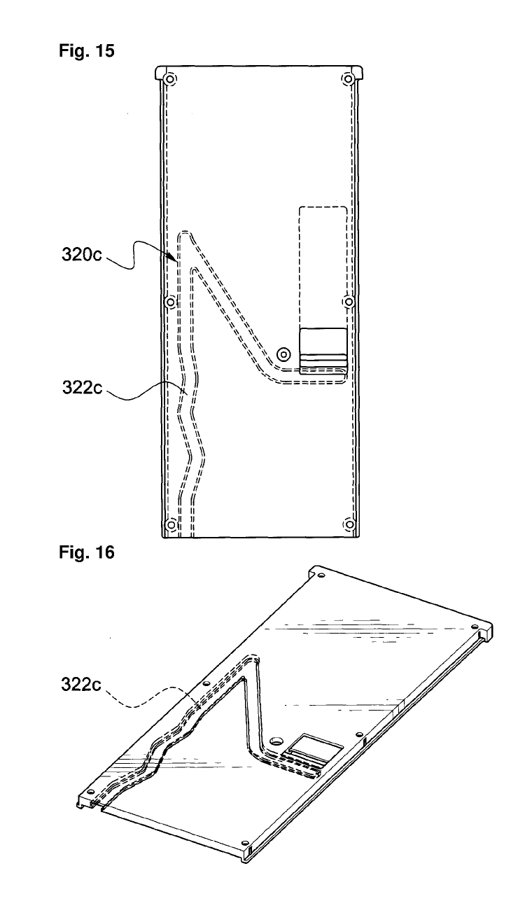

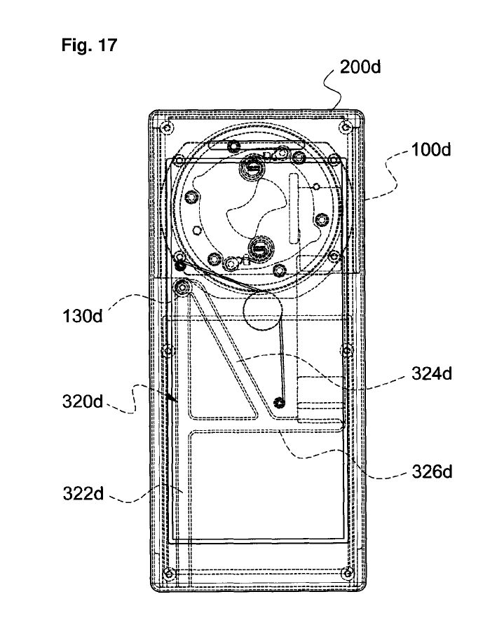

FIGS. 15 and 16 are a plan view and a perspective view showing a fourth embodiment of the present invention, and FIG. 17 is a plan view showing a fifth embodiment of the present invention. In these figures, guide grooves are variations of the first embodiment, which guide sliding and rotating motions at the same time.

In a device realizing vertical sliding and rotation motions of the present invention at the same time, a guide groove (320c) is obtained by changing a little from a basic linear groove described in the above embodiments and changing a vertical groove portion (322c) to a zigzag type by applying a little bit of bending as shown in FIGS. 15 and 16. Thereby, in a sliding motion of a first body (not shown), a guide protrusion (not shown) moves along it and the first body also slides with a slight vibration. Since this kind of vibration can be felt by a user's hand, the user can feel the operation. Therefore, the user can experience unique interest in using a mobile phone having a zigzag guide groove (320c).

In certain embodiments, the guide groove (320d) may make the slope angle of a guide groove (320d) larger or smaller, and extend a horizontal groove portion (326d) up to a vertical groove portion (322d) such that the horizontal groove portion (326d) is connected with a tilted groove portion (324d) and the vertical groove portion (322d). In such a case, when a first body (200d) and a second body (100d) rotate from overlapped state to a T-shape, a guide protrusion (130d) may move to a horizontal groove portion (326d) via a tilted groove portion (324d), and when they rotate from the T-shape to the overlapped state, it may return directly from the horizontal groove portion (326d) via the vertical groove portion (322d). In such a case, a fast returning motion may be obtained.

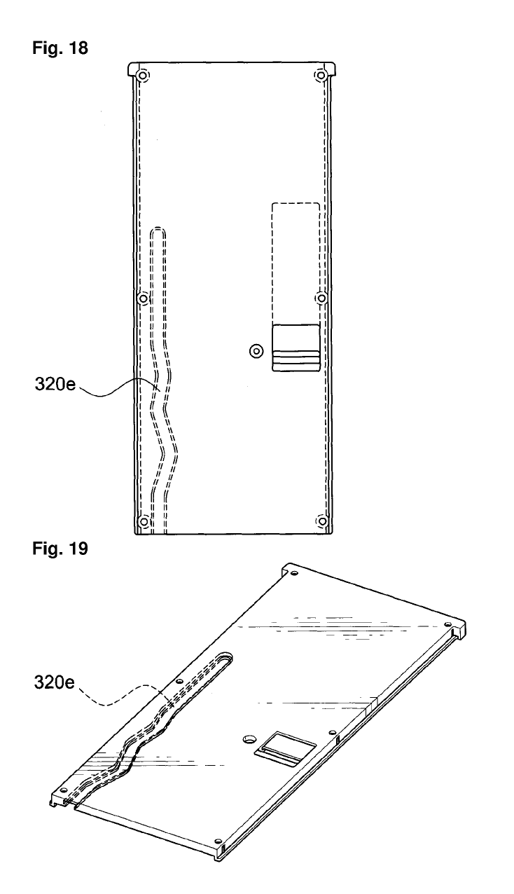

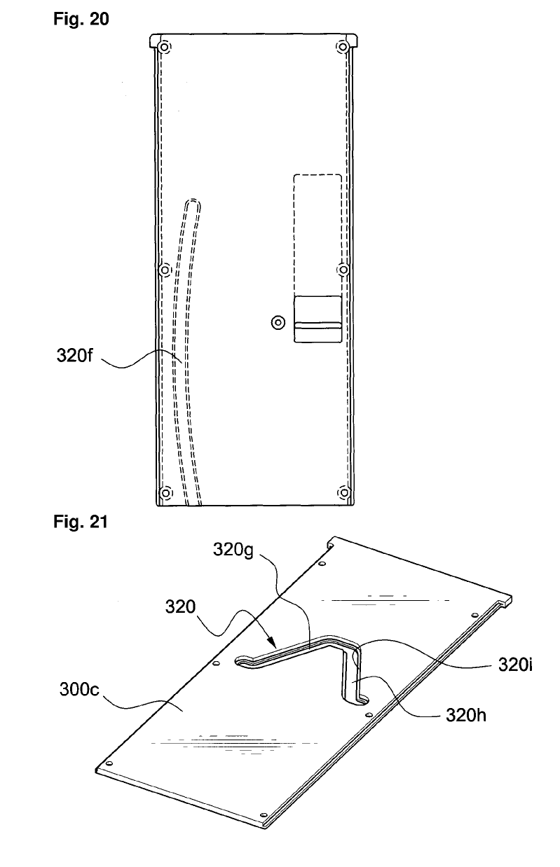

FIGS. 18 and 19 are a plan view and a perspective view showing a sixth embodiment of the present invention, a variant of the second embodiment. Also, FIG. 20 is a plan view showing the seventh embodiment, a variant of the second embodiment.

In the sliding device of the present invention, a guide groove (320e) may comprise a vertical groove portion only as shown in FIGS. 18 and 19, but can be changed to a zigzag shape by applying a little of bending to a straight line. The operation and effect of this case are same as those of the fourth embodiment described in the above.

In other embodiments of the invention, a guide groove (320f) may comprise a vertical groove portion only, but it is possible to change from a straight line shape to a slowly curved shape getting more convex as approaching toward a middle portion as shown in FIG. 20. In this case, in a sliding motion, a guide protrusion moves along a curved vertical groove portion and a first body slides in a direction of up-down on a second body with a slight left-right motion. This also may give the user various and unique interest. In illustrated embodiment, the guide groove (320f) has a shape convex toward outside, but the same effect can be obtained with a shape convex toward inside.

In a case of straight sliding step and rail, the rail plate used in the embodiments of FIGS. 18 and 20 should be installed rotatably to a rotation member as in the first embodiment.

FIGS. 15-20 show variations of guide grooves for guiding sliding and/or rotating motions in the present invention, and the guide grooves of the present invention may be changed to various shapes, which were not disclosed here, as long as they have structures enabling the operations.

FIG. 21 is a view of a guide groove according to another embodiment of the invention.

In certain embodiments, a guide groove (320) provided in a slide plate (300c) may comprise a upward tilted groove portion (320g) rising from a left side to a right side and a downward tilted groove portion (320h) descending again around the upward tilted groove portion (320g). Here, the guide groove (320) may be penetrated through top to bottom. And, a latch step (320i) may be formed along an inner surface of the guide groove (320).

When the guide groove (320) is formed as shown in FIG. 21, the first body can be rotated in a desired direction, clockwise or counterclockwise, and opened.

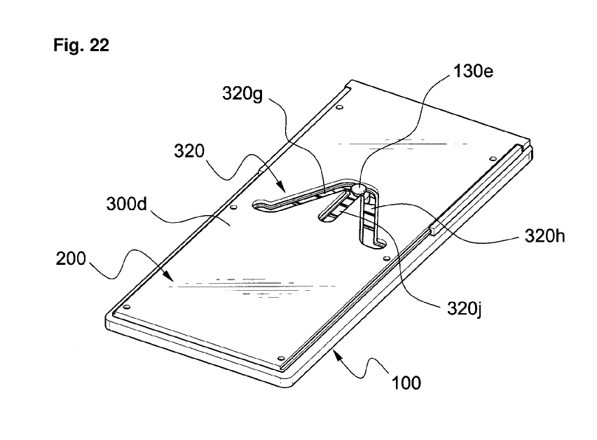

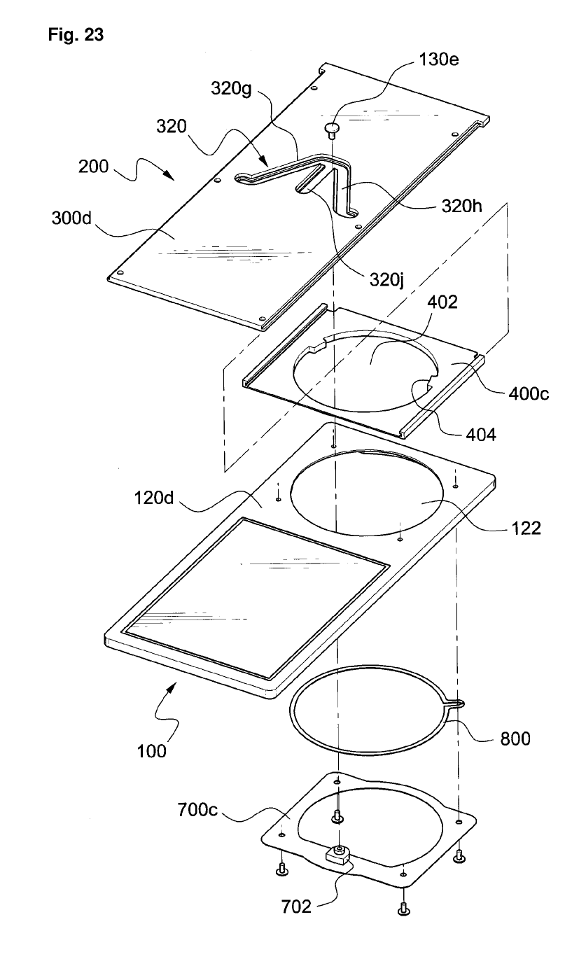

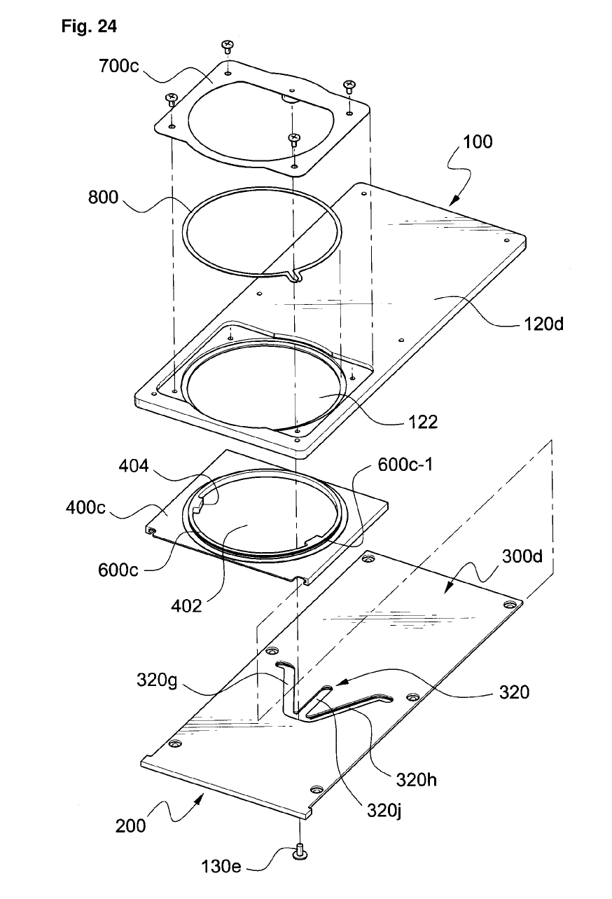

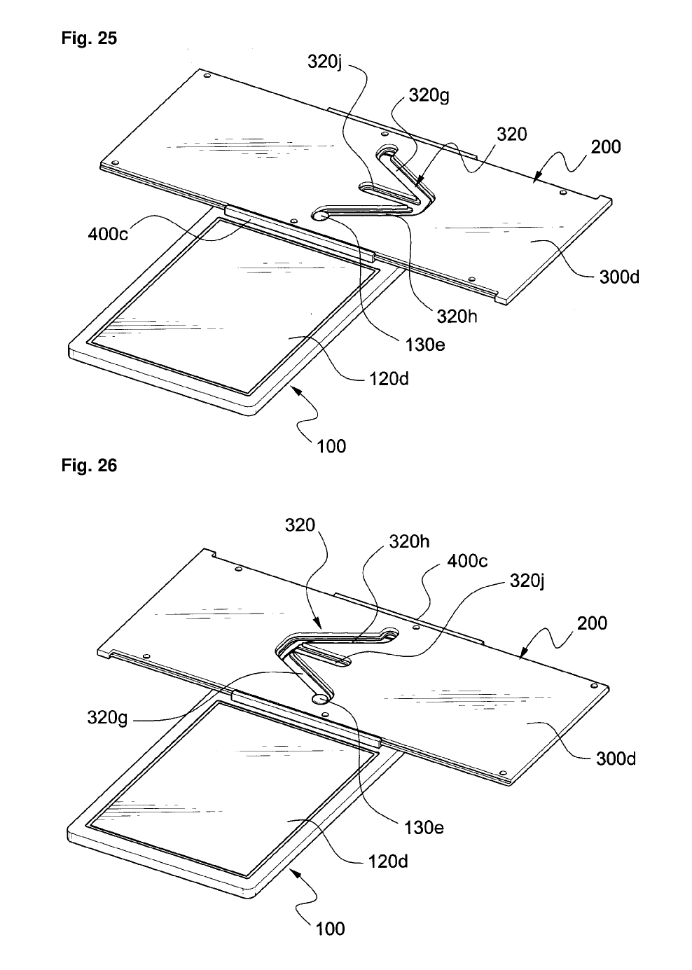

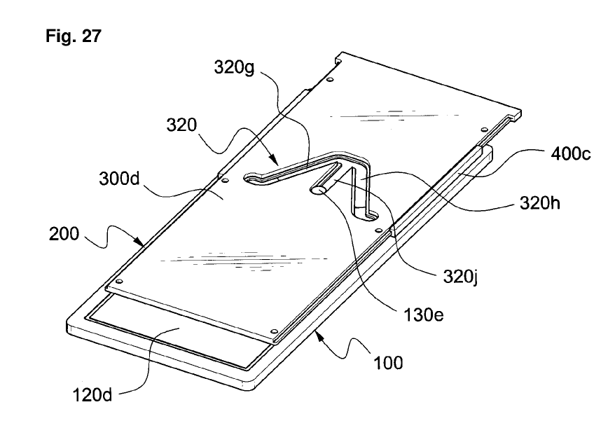

FIG. 22 is a perspective view showing a sliding device according to still another embodiment of the invention, FIG. 23 an exploded perspective view showing the sliding device of FIG. 22, FIG. 24 an exploded perspective view showing FIG. 23 as viewed from below, FIG. 25 is a perspective view showing a status of a first body rotated and opened clockwise, FIG. 26 is a perspective view showing a status of a first body rotated and opened counterclockwise, and FIG. 27 is a perspective view showing a status of a first body opened upward.

In certain embodiments of the invention, a top-to-bottom extension groove portion (320j) for sliding in a direction of top to bottom may be further formed between the upward tilted groove portion (320g) and the downward tilted groove portion (320h) so as to guide a guide protrusion (130e) in the direction of top to bottom and to slide the second body (100) top to bottom in order to open. In such a case, opening the first body (200) by clockwise rotation, counterclockwise rotation, and top-to-bottom linear slide. Also, it is also possible to provide more gap for the slide plate (300d) to slide downward by adjusting the location of the rail plate (400c), and to further form a linear or tilted groove above the top-to-bottom extension groove portion (320j).

And, a hole (402) may be formed in the rail plate (400c), a stopper (404) protruding from inner surface of the hole (402) may be formed toward inside, a rotation member (600c) may be formed at a bottom surface thereof so as to protrude integrally and downward, and an insertion groove (600c-1) may be formed on the side surface of the rotation member (600c). The rotation member (600c) may be inserted into the rotation member installation portion (122) having a shape of through hole from the top side and the ring plate (800) installed in the insertion groove (600c-1) at a bottom side of the top plate (120d), so that the rail plate (400c) is able to rotate on the spot without falling off from the top plate (120d).

In such a case, a protrusion (702) may be formed in a support plate (700c) installed on a bottom surface of the top plate (120d), such that the stopper (404) stops at a specific angle. A guide protrusion (130e) may be engaged to the protrusion (702).

In the state of FIG. 22, for rotating clockwise and opening the slide plate (300d), if pushing a lower portion of the slide plate (300d) to the left, the slide plate (300d) rotates clockwise and moves riding the rail plate (400c) while the downward tilted groove portion (320h) is applied with a force sideways by the guide protrusion (130e), and then it rotates clockwise and opens while keeping a left-right symmetry as shown in FIG. 25. At this moment, the protrusion (702) is latched at one side of the stopper (404).

In the state of FIG. 22, for rotating counterclockwise and opening the slide plate (300d), if pushing a lower portion of the slide plate (300d) to the right, the slide plate (300d) rotates counterclockwise and moves riding the rail plate (400c) while the upward tilted groove portion (320g) is applied with a force sideways by the guide protrusion (130e), and then it rotates counterclockwise and opens while keeping a left-right symmetry as shown in FIG. 26. At this moment, the protrusion (702) is latched at the other side of the stopper (404).

In another embodiments of the invention, as shown in FIG. 27, the slide plate (300d) can be opened or closed by moving the slide plate (300d) vertically along a straight line.

If installing circuit board, button, display, etc. to the sliding device described referring to FIGS. 1-27 and connecting electrically to necessary components by cable, a portable electronic device adopting a sliding device according to the present invention is provided.

In certain embodiments of the present invention, the rail plate or the slide plate may become the first body or the second body for themselves.

### APPLICATIONS TO INDUSTRY

The present invention may be applied to various types of electronic devices, construction structures, etc., requiring a linear sliding and/or rotating sliding operation, such as mobile phones, PDAs, portable game machines, electronic schedulers, electronic dictionaries, etc.

1. A sliding device combining a first body and a second body slidably with respect to each other, the sliding device comprising:
a sliding step provided in the first body;
a sliding rail provided in a second body corresponding to the sliding step, engaging, and sliding the sliding step;
a guide groove formed in one of the first body and the second body along a direction of sliding; and
a guide protrusion provided in the other of the first body and the second body, protruding toward the guide groove, engaging the guide groove, and moving along the guide groove during the sliding motion between the first body and the second body.

2. The sliding device of claim 1, wherein the sliding rail, the sliding step, and the guide groove are provided in a straight line or in a curved line which is convex toward one side direction in a middle portion.

3. The sliding device of claim 1, wherein one of the sliding step and the sliding rail, which is provided at the other of the first body and the second body, is installed slidably through a rotation member installation portion, and the guide groove comprises one selected from the group consisting of a linear groove, a curved groove which is convex toward a side direction, and a groove having more than one zigzag bendings to right and left sides.

4. A sliding device comprising:
a first body in which a guide groove having a tilted groove portion tilted in a direction of width is formed and comprising a slide plate with a sliding step at a side;
a second body having a rotation member installation portion and a guide protrusion inserted to the guide groove, when the first body rotates, the guide protrusion applying a force to a side surface of the guide groove and allowing the first body perform a sliding motion;
a rotation member provided rotatably at the rotation member installation portion; and
a rail plate engaged to a rotation member and comprising a rail engaging the sliding step so as to allow the first body to perform the sliding motion along with rotation.

5. The sliding device of claim 4, further comprising a horizontal groove member connected to a side of the tilted groove portion.

6. The sliding device of claim 4, wherein the guide groove comprises an upward tilted groove portion formed along a path which gets higher as going from one side to the other side and a downward tilted groove portion formed along a path which gets lower from the upward tilted groove portion.

7. The sliding device of claim 6, further comprising a top-bottom extension groove portion formed along a path which is connected between the upward tilted groove portion and the downward tilted groove portion and extended top to bottom.

8. The sliding device of claim 4, wherein the second body comprises a top plate having a through hole for the rotation member installation portion, and the rotation member comprises a circular plate member inserted into the through hole and engaged to the rail plate and a latch member having a diameter larger than the rotation member installation portion.

9. The sliding device of claim 8, wherein a cam groove is formed in the center of the rotation member, and further comprising a tension roller device having an end fixed to the second body, inserted into the cam groove, and sticking to an inner wall of the rotation member.

10. The sliding device of claim 9, wherein the cam groove includes a curved guide path and stop grooves disposed with an interval in the curved guide path, and wherein the tension roller device is formed with a pair facing each other and comprises: a torsion spring fixed to the second body; and a roller sticking to the guide path, providing a recovering force toward outside, and staying at the stop groove in the rotational motion so as to stay at a stop state.

11. The sliding device of claim 4, wherein the second body comprises a top plate having a through hole as the rotation member installation portion, and the rotation member comprises: a circular protrusion which is installed on a bottom surface of the rail plate and inserted into the through hole so as to support the rail plate to rotate in a right or left direction; and a ring body which is engaged to the circular protrusion at a bottom portion of the top plate so as to prevent the circular protrusion from falling off the through hole.

12. The sliding device of claim 4, wherein the guide groove further comprises a vertical groove portion which is connected to the other side of the tilted groove portion and formed in a direction of length of the first body.

13. The sliding device of claim 12, wherein the vertical groove portion comprises one from a linear groove, a curved groove having a middle portion which is convex toward one side and a groove which has one or more bendings to the right and left sides in zigzag.

14. The sliding device of claim 4, further comprising a torsion spring, which has both ends rotatably connected to the first body and the second body respectively, rotates and performs compression and recovery following the sliding of the first body with respect to the second body, and pushes the first body by the rotation angle in a different direction.

15. A portable electronic device comprising a sliding device of claim 1.

16. The sliding device of claim 5, wherein the guide groove further comprises a vertical groove portion which is connected to the other side of the tilted groove portion and formed in a direction of length of the first body.

17. The sliding device of claim 8, wherein the guide groove further comprises a vertical groove portion which is connected to the other side of the tilted groove portion and formed in a direction of length of the first body.

18. The sliding device of claim 9, wherein the guide groove further comprises a vertical groove portion which is connected to the other side of the tilted groove portion and formed in a direction of length of the first body.

19. The sliding device of claim 11, wherein the guide groove further comprises a vertical groove portion which is connected to the other side of the tilted groove portion and formed in a direction of length of the first body.

20. A portable electronic device comprising a sliding device of claim 4.
